(19) United States
(12) Patent Application Publication
(10) Pub. No.: US 2010/0059762 A1
(43) Pub. Date: Mar. 11, 2010

(54) HEAT REMOVAL FACILITATED WITH DIAMOND-LIKE CARBON LAYER IN SOI STRUCTURES

(75) Inventors: Tim Z. Hossain, Austin, TX (US); Daniel E. Posey, Granite Shoals, TX (US)

Correspondence Address: TUROCY & WATSON, LLP, 127 Public Square, 57th Floor, Key Tower, CLEVELAND, OH, 44114, US

(73) Assignee: SPANSION LLC, Sunnyvale, CA (US)

(21) Appl. No.: 12/206,117

(22) Filed: Sep. 8, 2008

(51) Int. Cl. H01L 29/15; H01L 21/30

(52) U.S. Cl. 257/77; 438/455; 257/E21.211; 257/E29.072

(57) ABSTRACT

Described are Silicon-on-Insulator devices containing a diamond-like carbon layer, methods of making the Silicon-on-Insulator devices, and methods of using the Silicon-on-Insulator devices.

### TECHNICAL FIELD

Described are Silicon-on-Insulator devices containing a diamond-like carbon layer, methods of making the Silicon-on-Insulator devices, and methods of using the Silicon-on-Insulator devices.

### BACKGROUND

Silicon-on-Insulator (SOI) technology is of growing importance in the field of integrated circuits. SOI technology involves forming transistors in a relatively thin layer of semiconductor material overlying a layer of silicon dioxide. More particularly, SOI technology is characterized by the formation of a thin silicon layer (device region) for formation of the active devices over a silicon dioxide layer, which is in turn formed over a silicon substrate. Transistor sources and drains are formed, for example, by implantations into the silicon layer while transistor gates are formed by forming a patterned oxide and conductor layer structure.

Such structures provide a significant gain in performance by having lower parasitic capacitance (due to the insulator layer) and increased drain current due to floating body charging effects (since no connection is made to the channel region and charging of the floating body provides access towards a majority of carriers which dynamically lower the threshold voltage, resulting in increased drain current). Devices, such as metal oxide silicon field effect transistors (MOSFET), have a number of advantages when formed on SOI wafers versus bulk silicon MOS transistors. These advantages include: reduced source/drain capacitance and hence improved speed performance at higher-operating frequencies; reduced N+ to P+ spacing and hence higher packing density due to ease of isolation; absence of latch-up; lower voltage applications; and higher “soft error” upset immunity (i.e., the immunity to the effects of alpha particle strikes).

Although there are significant advantages associated with SOI technology, there are significant disadvantages as well. The disadvantages are significant enough to limit the overall use and application of SOI technology. For example, poor heat removal from devices on an SOI substrate is a notable disadvantage compared to conventional semiconductor devices formed over monocrystalline silicon. Electrical devices generate heat, and the inability to remove or dissipate the heat results in poor and/or inconsistent performance of the electrical devices, or even in some instances device and/or substrate degradation.

There is poor heat removal for devices on SOI substrates primarily because of the presence of the silicon dioxide layer within the substrate. More specifically, the silicon dioxide layer has a markedly lower thermal conductivity than the thermal conductivity of conventional bulk silicon (typically used as semiconductor substrates), which typically surrounds semiconductor devices. For example, the thermal conductivity of silicon dioxide is about 1.4 W/m° C. while the thermal conductivity of conventional bulk silicon is about 150 W/m° C. As a result, the buried oxide layer undesirably insulates thermally the device region in SOI substrates.

### SUMMARY

Provided herein are SOI structures having improved heat removal characteristics (from the device layer). By forming an SOI structure as described herein, improved performance of microelectronic devices formed thereon is facilitated. Moreover, forming an SOI structure as described herein does not degrade or deleteriously affect the advantageous properties and characteristics commonly associated with SOI technology (improved speed performance at higher-operating frequencies, higher packing density, absence of latch-up, lower voltage applications, and higher “soft error” upset immunity).

In one aspect of the invention, an SOI structure contains a diamond-like carbon layer between a silicon device layer and an insulation layer.

In another aspect of the invention, an SOI structure contains a silicon substrate layer, a buried insulation layer over the silicon substrate layer, a diamond-like carbon layer over and adjacent at least 50% of the horizontal surface of the insulation layer, and a silicon device layer over the diamond-like carbon layer.

In yet another aspect of the invention, an SOI structure contains a diamond-like carbon layer between a silicon device layer and an insulation layer, where the boundary between the silicon device layer and the diamond-like carbon layer is not co-planar over the entire boundary.

### BRIEF DESCRIPTION OF DRAWINGS

FIG. 1 is a cross-sectional view of a first structure used to make an SOI substrate according to one embodiment of the present invention.

FIG. 2 is a cross-sectional view of a second structure used to make an SOI substrate according to one embodiment of the present invention.

FIG. 3 is a cross-sectional view of a bonded structure used to make an SOI substrate according to one embodiment of the present invention.

FIG. 4 is a cross-sectional view of an SOI substrate according to one embodiment of the present invention.

FIG. 5 is a cross-sectional view of a bulk silicon structure used to make an SOI substrate according to one embodiment of the present invention.

FIG. 6 is a cross-sectional view of an etched bulk silicon structure used to make an SOI substrate according to one embodiment of the present invention.

FIG. 7 is a cross-sectional view of a first structure used to make an SOI substrate according to one embodiment of the present invention.

FIG. 8 is a cross-sectional view of a second structure used to make an SOI substrate according to one embodiment of the present invention.

FIG. 9 is a cross-sectional view of a bonded structure used to make an SOI substrate according to one embodiment of the present invention.

FIG. 10 is a cross-sectional view of an SOI substrate according to one embodiment of the present invention.

FIG. 11 is a cross-sectional view of an SOI substrate according to one embodiment of the present invention.

### DETAILED DESCRIPTION

By forming an SOI structure having improved heat removal characteristics, the performance of devices subsequently formed on the SOI structure can be substantially improved. While not wishing to be bound to any theory, it is believed that by forming a diamond-like carbon (DLC) layer in addition to the silicon dioxide layer, it is consequently possible to increase the amount of heat that may be removed (and/or increase the rate at which heat may be removed) from the device layer of the SOI structure by dissipating the heat through the diamond-like carbon layer. Heat generated by heat generating microelectronic devices such as a MOSFET, MIM, non-volatile memory cell, is removed by conduction through the DLC layer. This is because temperature flows from relatively hot locations to relatively cold locations within the DLC layer. Improving the removal of heat from the device layer consequently improves the performance and increases the life of devices, such as MOSFETs, formed on the device layer of the SOI structure.

A DLC layer is positioned adjacent and above the buried insulation layer of an SOI structure. In the completed SOI structure, the DLC layer acts as a heat spreader/dissipater, allowing heat to flow away from hot localities in the device layer (such as underneath microelectronic devices and/or high density regions). The DLC layer has relatively high thermal conductivity and thus facilitates the transfer of heat away from and/or evenly spreads (preventing local build-up of) heat generated in the device layer of the SOI structure. Some forms of DLC are also known as tetrahedral amorphous carbon and DLC can be comprised of all sp3 hybridized carbon or a mixture of sp3 and sp2 hybridized carbon. DLC has a thermal conductivity of about 1000 to about 2500 W/m° K that is higher than the thermal conductivity of silicon dioxide (about 1.4 W/m° K), polycrystalline silicon (about 75 to about 125 W/m° K) and the thermal conductivity of monocrystalline silicon (about 150 W/m° K).

Furthermore, DLC has a dielectric constant from about 5 to about 7, and a resistivity of about 1012 Ω/cm. Such electrical characteristics, although different from silicon dioxide (silicon dioxide has superior electrical insulation characteristics), provide additional electrical insulation benefits to the SOI structure.

The DLC layer, as its name implies, contains diamond-like carbon and forms a stable heat transfer layer that adheres well to silicon and insulator materials (such as silicon dioxide).

The thermal conductivity of the DLC layer is relatively high compared to the thermal conductivity of the insulation layer and bulk silicon. In one embodiment, the thermal conductivity of the DLC layer is at least 100 times higher than the thermal conductivity of the insulation layer. In another embodiment, the thermal conductivity of the DLC layer is at least 200 times higher than the thermal conductivity of the insulation layer. In yet another embodiment, the thermal conductivity of the DLC layer is at least 300 times higher than the thermal conductivity of the insulation layer. The DLC layer can be formed to any thickness suitable for facilitating heat removal from the subsequently formed device layer. The DLC layer can be formed through substantially the entire SOI structure, or the DLC layer can be formed in regions where heat generation is relatively high. Typically, the DLC layer is formed in at least about 50% of the horizontal surface area of the SOI structure. In another embodiment, the DLC layer is formed in at least about 50% of the horizontal surface area of the SOI structure. In one embodiment, generally, the thickness of the DLC (in regions where present) is from about 100 Å to less than 5,000 Å, or from about 100 Å to about 10,000 Å. In another embodiment, the thickness of the DLC layer is from about 200 Å to about 4,000 Å. In another embodiment, the thickness of the DLC layer is from about 300 Å to about 3,000 Å. In one embodiment, the thickness of the DLC layer is less than 5,000 Å. In this connection, improved thermal conductivity results are often obtained when the DLC layer is less than 5,000 Å.

Due to the expensive nature of the DLC starting materials and/or the expensive nature of forming a DLC layer, the DLC layer may have at least two different thicknesses in different regions of the SOI structure. In another embodiment, the DLC layer may have at least three different thicknesses in different regions of the SOI structure. Generally in regions where heat generation is relatively high, the DLC layer is relatively thick while in regions where heat generation is relatively low or of little concern, the DLC layer is relatively thin or non-existent.

In one embodiment, the thickness of the DLC layer (in regions where present) is from about 100 Å to less than 5,000 Å in a first region, and from about 100 Å to about 10,000 Å in a second region. In another embodiment, the thickness of the DLC layer is from about 200 Å to about 2,500 Å in a first region, and from about 200 Å to less than 5,000 Å in a second region. In yet another embodiment, the thickness of the DLC layer is from about 300 Å to about 2,000 Å in a first region, and from about 300 Å to about 4,000 Å in a second region. In still yet another embodiment, the thickness of the DLC layer is at least about 50% less in thickness in a first region compared to the thickness in a second region. The thickness of the DLC layer can be greater than, less than, or about equal to the thickness of the silicon dioxide layer.

The DLC layer is formed in any suitable manner over the bulk or monocrystalline silicon layer including various deposition techniques. This is accomplished by physical vapor deposition (PVD) and particularly sputtering, or chemical vapor deposition (CVD). Such methods are known in the art.

After the DLC layer is deposited on the silicon that subsequently forms the device layer, an insulation layer is formed thereover using any suitable technique including CVD and wet and dry oxidation processes. This structure containing the DLC layer is then bonded to a second structure containing either bulk silicon or an insulation layer on bulk silicon (typically the same structure, but without the DLC layer). The two structures are fused at the insulation layer-DLC layer or at the respective insulation layers, and the bulk silicon of the first structure is optionally polished back to a desired thickness to form an SOI substrate. Fusing the two structures is conducted under heat for a suitable period of time. For example, in one embodiment, the two structures are fused at a temperature from about 900° C. to about 1,400° C. for a time from about 20 minutes to about 6 hours. In another embodiment, the two structures are fused at a temperature from about 1,000° C. to about 1,200° C. for a time from about 40 minutes to about 4 hours.

The two structures (the structure containing the diamond-like carbon layer on bulk silicon and the structure containing bulk silicon) can have insulation layers that have similar or different thicknesses. In one embodiment, the two structures have insulation layers that have similar thicknesses (a size within about 5% of each other). In another embodiment, the two structures have insulation layers that have different thicknesses (one thickness is at least about 50% greater in size than other, or one thickness is at least about 100% greater in size than other).

The SOI structure described herein has a bulk or monocrystalline silicon layer, a buried insulation layer over the bulk silicon layer, a DLC layer over the buried insulation layer, and a silicon layer (device layer) over the DLC layer (although the DLC layer may not be formed over the entire structure). The buried insulation layer typically contains silicon dioxide, although the insulation layer may contain any suitable insulating or oxide material. The buried insulation layer has thickness from about 100 Å to about 5,000 Å. In another embodiment, the buried insulation layer has thickness from about 400 Å to about 4,000 Å. In yet another embodiment, the buried insulation layer has thickness from about 500 Å to about 3,000 Å. The device layer has thickness from about 500 Å to about 5,000 Å. In another embodiment, the device layer has thickness from about 1,000 Å to about 3,000 Å.

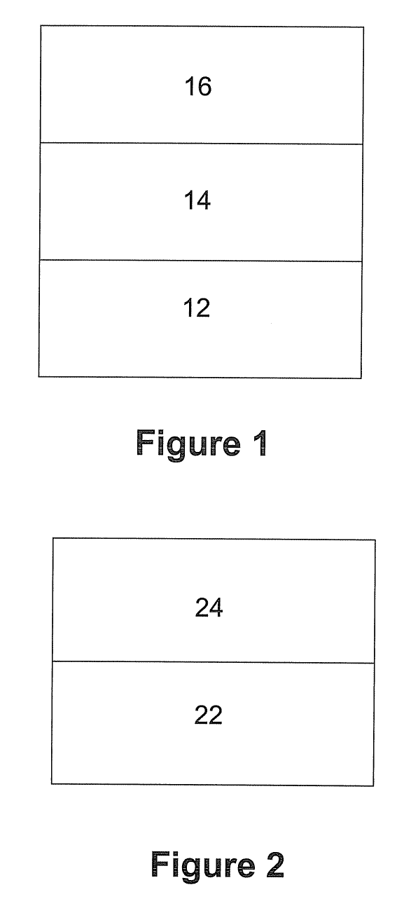

Referring to FIGS. 1 to 4, a specific example of the present invention is described. Specifically referring to FIG. 1, a first structure 10 is formed. The first structure 10 is a DLC containing structure. Initially, a bulk silicon substrate or wafer 12 is provided. A DLC layer 14 is deposited over the bulk silicon substrate 12. In this embodiment, the DLC layer is deposited over the bulk silicon substrate 12 using CVD techniques to a thickness of about 700 Å. An insulation layer 16 containing silicon dioxide is then formed over the DLC layer 14 by CVD techniques. Either low pressure chemical vapor deposition (LPCVD) or plasma enhanced chemical vapor deposition (PECVD) may be employed. In this embodiment, the insulation layer 16 is formed by PECVD using either silane and oxygen or silane and nitrous oxide. The insulation layer 16 has a thickness of about 1,000 Å.

Referring to FIG. 2, a second structure 20 is provided. The second structure 20 contains a bulk silicon layer 22 and an insulation layer 24 thereover. In this embodiment, the insulation layer 24 contains silicon dioxide. Also in this embodiment, the thickness of the insulation layer 24 is about 1,000 Å.

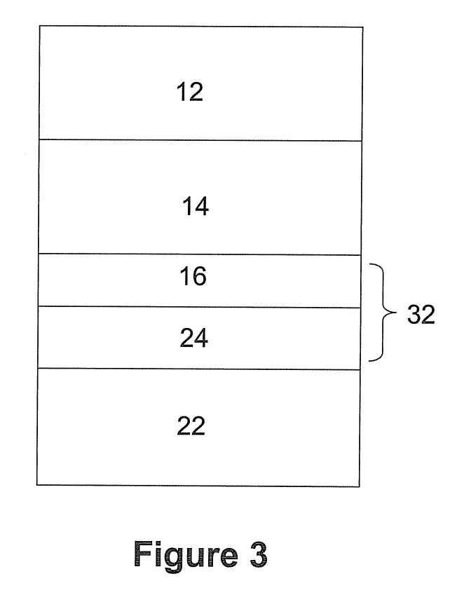

Referring to FIG. 3, the first structure 10 is bonded to the second structure 20 at the respective insulation layers 16 and 24. The respective insulation layers 16 and 24 are fused by application of heat for a sufficient period of time to bond the first and second structures 10 and 20. For example, the first and second structures 10 and 20 are held together for about 2 hours under a temperature of about 1,100° C. Insulation layers 16 and 24 fuse to form a single insulation layer 32.

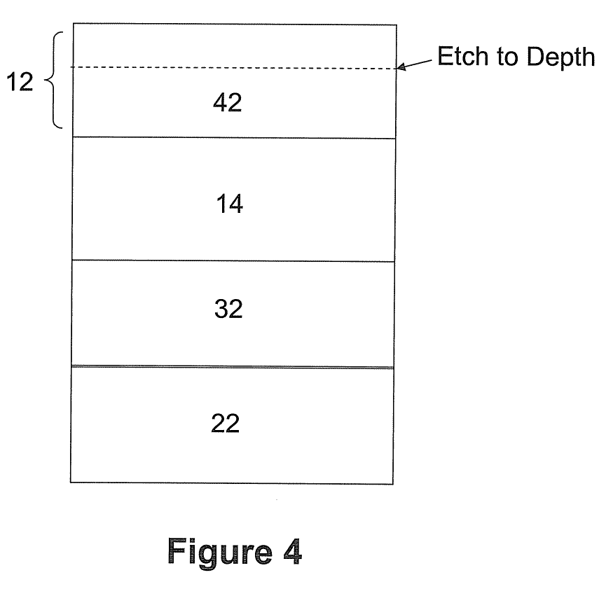

Referring to FIG. 4, the bulk silicon layer 12 of in FIG. 3 of the first structure 10 is etched to a desired thickness to provide an SOI substrate 40 and specifically a device layer 42. The SOI substrate 40 contains bulk silicon layer 22, DLC layer 14, buried insulation layer 32, and device layer 42. The thickness of the device layer 42 is about 1,500 Å. The thickness of the insulation layer 32 (formerly the insulation layers 16 and 24) is about 2,000 Å. The thickness of the DLC layer 14 remains about the same as initially deposited. The DLC layer 14 has a thickness that is about 35% of the thickness of the insulation layer 32.

The SOI substrate 40 has better heat removal properties due to the presence of the DLC layer 14. In particular, the high thermal conductivity of DLC (relative to silicon dioxide) removes heat that may locally accumulate in certain areas (typically near or under devices and/or conductive structures) of the device layer and insulation layer. The high thermal conductivity of DLC also dissipates heat that may locally accumulate in certain areas of the device layer and insulation layer (or distributes the heat throughout the DLC layer).

Referring to FIGS. 1 to 4, another specific example of the present invention is described. Specifically referring to FIG. 1, a first structure 10 is formed. The first structure 10 is a DLC containing structure. Initially, a bulk silicon substrate or wafer 12 is provided. A DLC layer 14 is deposited over the bulk silicon substrate 12. In this embodiment, DLC is deposited by CVD techniques over the bulk silicon substrate 12 to a thickness of about 1,800 Å. An insulation layer 16 containing silicon dioxide is then formed over the DLC layer 14 by CVD techniques. Either low pressure chemical vapor deposition (LPCVD) or plasma enhanced chemical vapor deposition (PECVD) may be employed. In this embodiment, the insulation layer 16 is formed by PECVD using either silane and oxygen or silane and nitrous oxide. The insulation layer 16 has a thickness of about 250 Å.

Referring to FIG. 2, a second structure 20 is provided. The second structure 20 contains a bulk silicon layer 22 and an insulation layer 24 thereover. In this embodiment, the insulation layer 24 contains silicon dioxide. Also in this embodiment, the thickness of the insulation layer 24 is about 250 Å.

Referring to FIG. 3, the first structure 10 is bonded to the second structure 20 at the respective insulation layers 16 and 24. The respective insulation layers 16 and 24 are fused by application of heat for a sufficient period of time to bond the first and second structures 10 and 20. For example, the first and second structures 10 and 20 are held together for about 3 hours under a temperature of about 1,050° C. Insulation layers 16 and 24 fuse for form a single insulation layer 32.

In another embodiment, the step of forming insulation layer 16 is omitted (not shown) and first structure 10 is bonded to second structure 20 at the respective DLC layer 14 and insulation layer 24. DLC layer 24 and insulation layer 16 are fused by application of heat for a sufficient period of time to bond the first and second structures 10 (with insulation layer 24 omitted) and 20. For example, the first and second structures 10 and 20 are held together for about 3 hours under a temperature of about 1,050° C.

Referring to FIG. 4, the bulk silicon layer 12 in FIG. 3 of the first structure 10 is etched to a desired thickness to provide an SOI substrate 40 and specifically a device layer 42. The SOI substrate 40 contains bulk silicon layer 22, DLC layer 14, buried insulation layer 32, and device layer 42. The thickness of the device layer 42 is about 2,000 Å. The thickness of the insulation layer 32 (formerly the insulation layers 16 and 24) is about 500 Å. The DLC layer 14 has a thickness that is about 360% of the thickness of the insulation layer 34.

The SOI substrate 40 has good heat removal properties due to the presence of the DLC layer 14. In particular, the high thermal conductivity of DLC (relative to silicon dioxide) removes heat that may locally accumulate in certain areas (typically near or under devices and/or conductive structures) of the device layer and insulation layer. The high thermal conductivity of DLC also dissipates heat that may locally accumulate in certain areas of the device layer and insulation layer (or distributes the heat throughout the DLC layer).

The disclosed device and methods facilitating heat removal from a device layer of a silicon-on-insulator substrate having bulk silicon, an insulation layer over the bulk silicon, and a silicon device layer over the insulation layer by forming a DLC layer between the silicon device layer and the insulation layer.

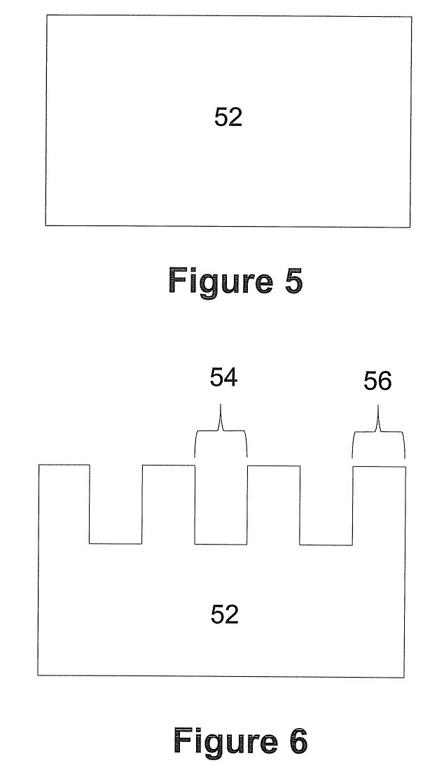

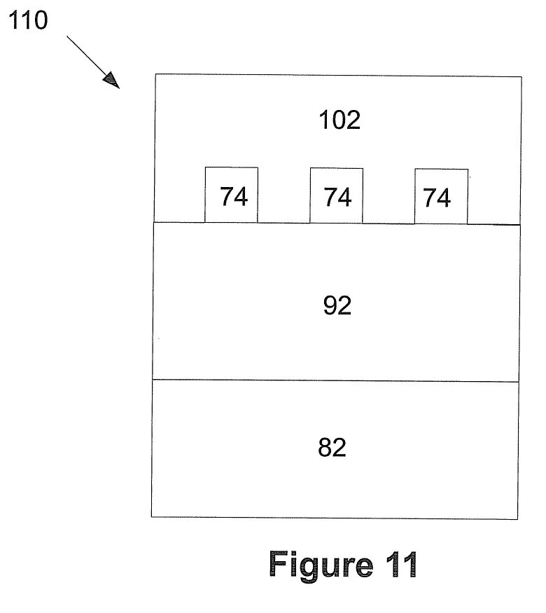

Referring to FIGS. 5 to 11, another specific example of the present invention is described. Specifically referring to FIG. 5, a silicon substrate 52 is provided.

Referring to FIG. 6, the surface of the bulk silicon substrate 52 is patterned or modified using lithography techniques. For example, a photoresist (not shown) is placed over the bulk silicon substrate 52. The photoresist is patterned and developed to expose a portion of the surface of the bulk silicon substrate 52. The exposed silicon substrate 52 is then etched to a predetermined depth and then the developed photoresist is removed. In one embodiment, the depth of the etched areas 54 is from about 50 Å to about 5,000 Å. In another embodiment, the depth of the etched areas 54 is from about 100 Å to about 2,500 Å. In yet another embodiment, the depth of the etched areas 54 is from about 200 Å to about 2,000 Å. In a further embodiment, a second photoresist is applied to silicon substrate 52 and patterned followed by a second etching process (not shown). The second etching process produces a second set of etched areas having a depth equal to any of the proceeding embodiments for etched areas 54. In yet another embodiment, a third or more photoresists are applied to silicon substrate 52, and a third or additional etching processes are performed to create as many sets of etched areas 54 as desired.

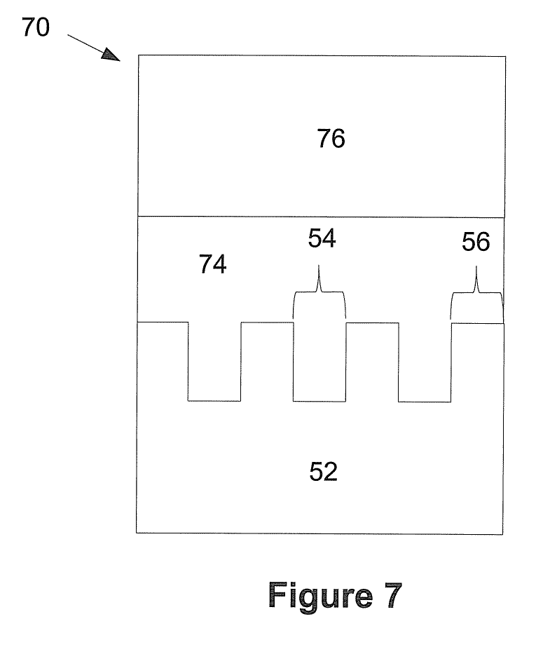

Referring to FIG. 7, a first structure 70 is a DLC containing structure. A DLC layer 74 is deposited over the etched bulk silicon substrate 52. In this embodiment, DLC is deposited by CVD techniques over the bulk silicon substrate 12 to a thickness of about 1,800 Å measured from the trough of etched areas 54. The boundary between the bulk silicon substrate 52 and the DLC layer 74 is not co-planar over the entire boundary. The surface of DLC layer 74 is then planarized. In one embodiment, the thickness of the DLC layer 74 measured from the unetched areas 56 of the silicon substrate 52 is at least about 50% of the thickness of the DLC layer 76 measured from the trough of the etched areas 54 of the silicon substrate 52. An insulation layer 76 containing silicon dioxide is then formed over the DLC layer 74 by CVD techniques. Either low pressure chemical vapor deposition (LPCVD) or plasma enhanced chemical vapor deposition (PECVD) may be employed. In this embodiment, the insulation layer 76 is formed by PECVD using either silane and oxygen or silane and nitrous oxide. The insulation layer 76 has a thickness of about 250 Å.

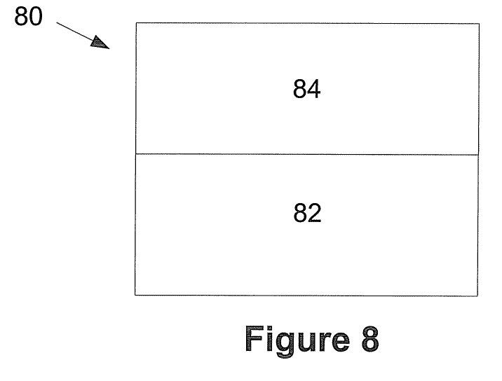

Referring to FIG. 8, a second structure 80 is provided. The second structure 80 contains a bulk silicon layer 82 and an insulation layer 84 there over. In this embodiment, the insulation layer 84 contains silicon dioxide. Also in this embodiment, the thickness of the insulation layer 84 is about 250 Å.

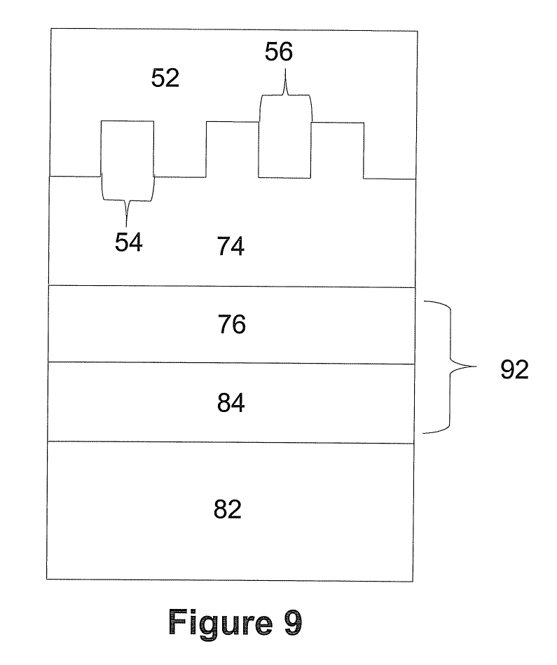

Referring to FIG. 9, the first structure 70 is bonded to the second structure 80 at the respective insulation layers 76 and 84. The respective insulation layers 76 and 84 are fused by application of heat for a sufficient period of time to bond the first and second structures 70 and 80. For example, the first and second structures 70 and 80 are held together for about 3 hours under a temperature of about 1,050° C. Insulation layers 76 and 84 fuse for form a single insulation layer 92.

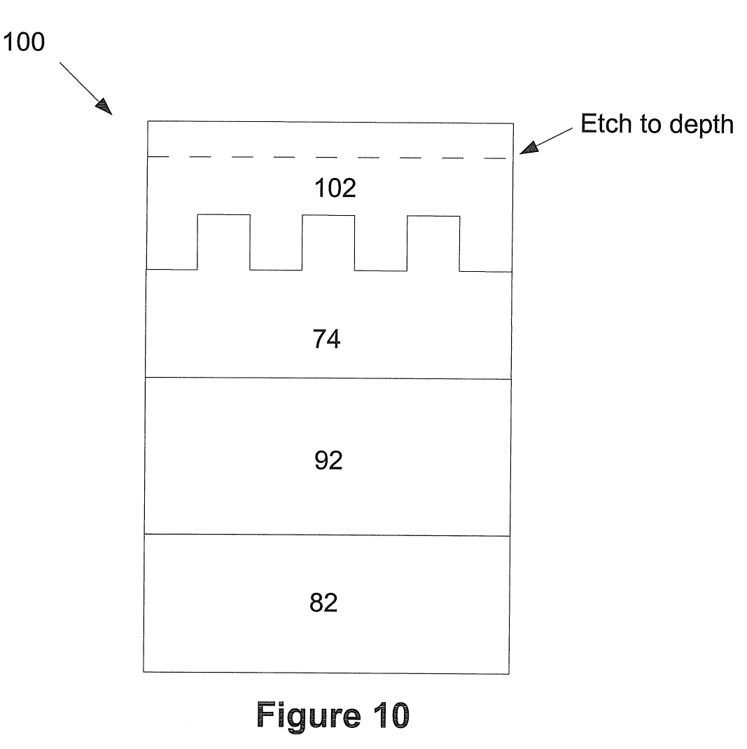

Referring to FIG. 10, the bulk silicon layer 72 in FIG. 9 is etched to a desired thickness to provide an SOI substrate 100 and specifically a device layer 102. The SOI substrate 100 contains bulk silicon layer 82, DLC layer 74, buried insulation layer 92, and device layer 1022. The thickness of the device layer 102 is about 2,000 Å. The thickness of the insulation layer 92 (formerly the insulation layers 76 and 84) is about 500 Å. The DLC layer 74 has a thickness that is about 360% of the thickness of the insulation layer 34 in the shallowest area of DLC layer 74.

An alternate embodiment of an SOI substrate 110 in accordance with an aspect of the invention is shown. SOI substrate 110 is formed in a similar manner as SOI substrate 100 shown in FIG. 10, except the DLC layer 74 is adjacent over only a portion of the horizontal surface of the insulation layer 92. In one embodiment, the DLC layer 76 is adjacent over at least 50% of the horizontal surface of the insulation layer 92. For SOI substrate 110, the depth of layer DLC layer 74 is substantially the same as the depth of etch areas 54 depicted in FIG. 6.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application.

What is claimed is:

1. A silicon-on-insulator structure, comprising:
a silicon substrate layer;
an insulation layer over the silicon substrate layer;
a DLC layer over and adjacent at least 50% of the horizontal surface of the insulation layer, the DLC layer having at least one region having a thickness from about 100 Å to less than 5,000 Å; and
a silicon device layer comprising silicon over the DLC layer.

2. The silicon-on-insulator structure of claim 1, wherein the DLC layer is positioned over and adjacent substantially the entire horizontal surface of the insulation layer.

3. The silicon-on-insulator structure of claim 1, wherein the DLC layer has a first thickness from about 200 Å to about 2,500 Å in a first region of the silicon-on-insulator structure, and a second thickness from about 200 Å to less than 5,000 Å in a second region of the silicon-on-insulator structure.

4. The silicon-on-insulator structure of claim 1, wherein the DLC layer has a thickness from about 200 Å to about 2,500 Å in a first region of the silicon-on-insulator structure, and in a second region of the silicon-on-insulator structure the silicon device layer contacts the insulation layer.

5. The silicon-on-insulator structure of claim 1, wherein the insulation layer comprises silicon dioxide having at least one region having a thickness from about 500 Å to about 5,000 Å.

6. The silicon-on-insulator structure of claim 1, wherein the boundary between the silicon device layer and the DLC layer is not co-planar over the entire boundary.

7. The silicon-on-insulator structure of claim 1, wherein the DLC layer has a region having a thickness from about 150 Å to about 800 Å.

8. A method of forming a silicon-on-insulator substrate, comprising:
providing a first silicon substrate;
forming a DLC layer over the first silicon substrate, the DLC layer having at least one region having a thickness from about 100 Å to about 5000 Å;
forming a first insulation layer over the DLC layer to provide a first structure;
providing a second structure comprising a second silicon layer and a second insulation layer;
bonding the first structure and the second structure together so that the first insulation layer is adjacent the second insulation layer; and
removing a portion of the first silicon layer thereby providing the silicon-on-insulator substrate.

9. The method of claim 8, wherein the first insulation layer and the second insulation layer have a combined thickness from about 100 Å to about 5,000 Å.

10. The method of claim 8, wherein the diamond-like layer is formed using chemical vapor deposition techniques.

11. The method of claim 8, wherein the DLC layer has a region having a thickness from about 150 Å to about 800 Å.

12. The method of claim 8, wherein the DLC layer has a region having a thickness from about 1,750 Å to about 2,500 Å.

13. The method of claim 8, wherein the first insulation layer and the second insulation layer have thicknesses that are within about 5% of each other in size.

14. The method of claim 8, wherein the silicon-on-insulator substrate comprises the first silicon substrate; the DLC based layer; a buried insulation layer comprising the first insulation layer and the second insulation layer; and a device layer comprising silicon.

16. The method of claim 8, further comprising:
forming a photoresist over the first silicon substrate;
patterning the photoresist;
developing the photoresist to expose a portion of the first silicon substrate;
etching the exposed portion of the first silicon substrate to a predetermined depth; and
removing the patterned photoresist.

17. A method of facilitating heat removal from a device layer of a silicon-on-insulator substrate comprising bulk silicon, an insulation layer over the bulk silicon, and a silicon device layer over the insulation layer, comprising:
forming a DLC layer having one of a first thickness from about 150 Å to about 800 Å and a second thickness from about 1,600 Å to about 2,750 Å in at least one region between the silicon device layer and the insulation layer.

18. The method of claim 17, wherein the DLC layer is formed by one of physical vapor deposition and chemical vapor deposition.

19. The method of claim 17, wherein the DLC layer has a thickness that is one of less than about 50% of the thickness of the insulation layer and greater than about 300% of the thicdmess of the insulation layer.

20. The method of claim 17, wherein the DLC layer has one or more regions having a thickness selected from the following: from about 200 Å to about 750 Å; from about 1,750 Å to about 2,500 Å; and from about 500 Å to about 3,000 Å.
